(19) United States
(12) Patent Application Publication
(10) Pub. No.: US 2025/0350030 A1
(43) Pub. Date: Nov. 13, 2025

(54) PACKAGE DEVICE WITH AN EMBEDDED OSCILLATION REGION

(71) Applicant: Taiwan Semiconductor Manufacturing Co., Ltd., Hsinchu (TW)

(72) Inventor: Wen-Shiang Liao, Toufen Township (TW)

(21) Appl. No.: 19/279,224

(22) Filed: Jul. 24, 2025

Related U.S. Application Data
(62) Division of application No. 17/895,502, filed on Aug. 25, 2022.

(51) Int. Cl. H01Q 9/04; H01L 21/48; H01L 23/00; H01L 23/13; H01L 23/14; H01L 23/31; H01L 23/498; H01L 25/00; H01L 25/065

(52) U.S. Cl. CPC H01Q 9/0407; H01L 21/4857; H01L 23/13; H01L 23/49822; H01L 25/0655; H01L 25/50; H01L 21/4853; H01L 23/147; H01L 23/3185; H01L 23/49816; H01L 23/49894; H01L 24/05; H01L 24/13; H01L 24/16; H01L 24/32; H01L 24/73; H01L 24/81; H01L 24/92; H01L 2224/05567; H01L 2224/05573; H01L 2224/05624; H01L 2224/13082; H01L 2224/13109; H01L 2224/13111; H01L 2224/13116; H01L 2224/13124; H01L 2224/13139; H01L 2224/13144; H01L 2224/13147; H01L 2224/13155; H01L 2224/13164; H01L 2224/16227; H01L 2224/32225; H01L 2224/73104; H01L 2224/73204; H01L 2224/81193; H01L 2224/81815; H01L 2224/92125; H01L 2924/0132; H01L 2924/0133

(57) ABSTRACT

Embodiments provide an integrated package device and method of forming the same, the device including a receive transmit integrated circuit die and embedded antenna. An oscillation region is aligned to the embedded antenna and a cavity is provided in the substrate to allow the passage of radio frequency (RF) signals into and out of the oscillation region.

### PRIORITY CLAIM AND CROSS-REFERENCE

This application is a divisional of U.S. patent application Ser. No. 17/895,502, filed on Aug. 25, 2022, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 10A, 10B, and 11 through 15 illustrate various views of intermediate steps during a process for forming a package component in accordance with some embodiments.

FIG. 16 illustrates a cross-sectional view of an integrated circuit die in accordance with some embodiments.

FIGS. 17 through 23A, 23B, and 24 through 25 illustrate various views of intermediate steps during a process for forming a package component in accordance with some embodiments.

FIG. 26 illustrates flow diagrams for a process of transmitting and receiving a transmission signal, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Devices with embedded antennas face unique challenges. Using printed circuit boards and/or complementary metal oxide semiconductors and associated metal layers may be used to form antennas, however, performance of such antennas is dominated by the large capacitance between metal layers. Further, layout is difficult to accommodate antennas to avoid interference from other metal structures in the devices. Also, space is limited and antennas may be weak or contain a lot of noise in transmission and/or reception. Integrated antennas typically suffer from process integration challenges, need large chip areas, and have high relative cost.

Embodiments provide a structure and device having an integrated antenna which is suitable for transmitting and receiving in 5G/6G radio frequency ranges, such as at around the nominal 12.4 GHz range for 5G/6G, and in the upcoming 5th generation around the nominal 5.8 GHz range and 5th generation high frequency ranges (29 GHz to 38 GHz and 77 GHz to 120 GHz.) Other frequencies are possible and contemplated.

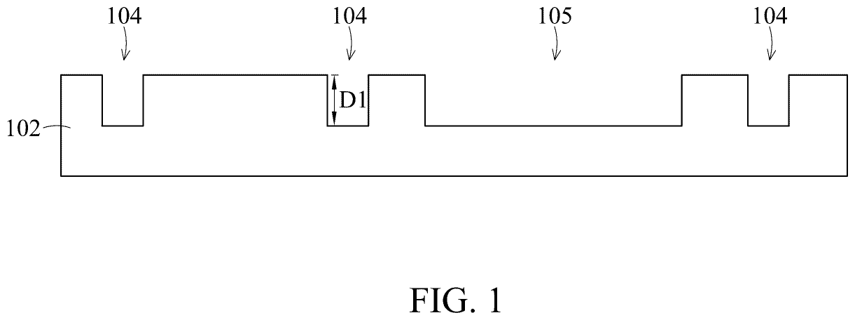

FIGS. 1 through 20 illustrate cross-sectional views and top down views of intermediate steps during a process for forming a first package component 100, in accordance with some embodiments. A first package region is illustrated. Additional package region may be formed at the same time as the first package region and may be understood as being like unto the first package region. The package regions are formed using the same base wafer substrate and later singulated and attached to a substrate, which is described following the formation of the first package component 100.

In FIG. 1, a substrate 102 is provided. The substrate 102 may be a semiconductor substrate, such as a bulk semiconductor, a semiconductor-on-insulator (SOI) substrate, or the like, which may be doped (e.g., with a p-type or an n-type dopant) or undoped. The substrate 102 may be a wafer, such as a silicon wafer having a thickness between about 500 and 2000 μm. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 102 is patterned to form recesses or trenches therein. The recesses 104 are formed for conductive vias which are subsequently used to route signals to subsequently provided integrated circuit dies. The recesses 105 are formed which align to a subsequently formed oscillation cavity for an integrated antenna and oscillation region. The recesses may have a depth D1 between about 50 μm and 200 μm, though other depths may be used. The recesses 104/105 may be formed using any suitable process, such as by an acceptable photoetching technique. For example, in one embodiment, a photoresist is formed over the substrate 102 and patterned into a photomask using a photolithography process. The photomask is then used to protect areas of the substrate 102 which are not to be etched. Then an etching technique, such as a reactive ion etch or wet etch may be used to etch the substrate 102 to a desired depth. For example, a timed etch may be used. While each of the recesses 104/105 is shown as having the same depth, in some embodiments, the recesses 104 may be deeper or shallower than the recesses 105. The recesses 104 may be any desired width, such as about 2 μm to about 50 μm and the recesses 105 may have a width and length (the length being in a perpendicular horizontal direction to the width) that corresponds to a subsequently formed antenna. In some embodiments, for example, the width and length of the recesses 105 may each be between about 3 mm and 80 mm.

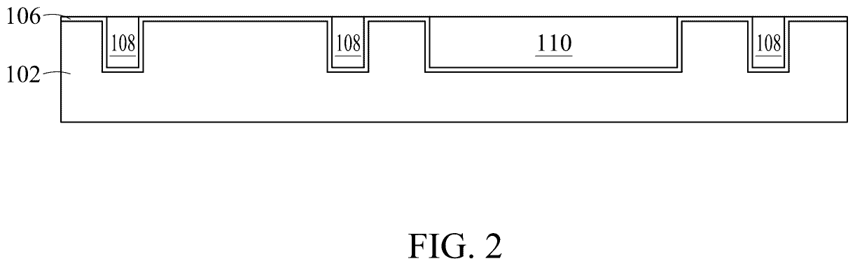

In FIG. 2, a liner layer 106 may be formed in each of the recesses 104/105. The liner layer 106 may be formed by a thermal oxidation process which uses steam or ambient oxygen to oxidize exposed portions of the substrate 102. When the substrate 102 is silicon, for example, the liner layer 106 may be silicon oxide. In other embodiments, the liner layer 106 may include a conformally deposited insulating material, such as silicon oxide, silicon nitride, silicon oxynitride, the like, or combination thereof, deposited by chemical vapor deposition (CVD), physical vapor deposition (PVD), atomic layer deposition (ALD), or the like.

After forming the liner layer 106, a metal fill 108 is deposited in the remaining portion of the recesses 104 and a metal fill 110 is deposited in the remaining portion of the recesses 105. The metal fill 108 and 110 may include any suitable material, such as copper, titanium, aluminum, silver, tungsten, cobalt, the like, or combinations (or alloys) thereof. The metal fill 108 and metal fill 110 may be deposited using any suitable process, such as by CVD, PVD, ALD, electroplating, electrochemical plating, and the like. In some embodiments, a seed layer is formed over the dielectric layer liner 106 in the recesses 104 and 105. The seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the recesses 104 and 105. The patterning forms openings through the photoresist to expose the seed layer in the recesses 104 and 105. A conductive material is formed in the openings of the photoresist and on the exposed portions of the seed layer. The conductive material may be formed by plating, such as electroplating or electroless plating, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metal fill 108 and metal fill 110. Portions of the metal fill 108 and 110 which may extend above the substrate 102 may be removed and leveled to the surface of the substrate 102 using a planarization process, such as a chemical mechanical polishing (CMP) process.

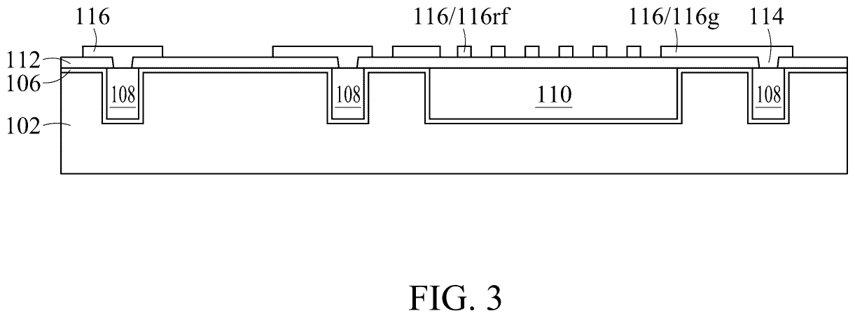

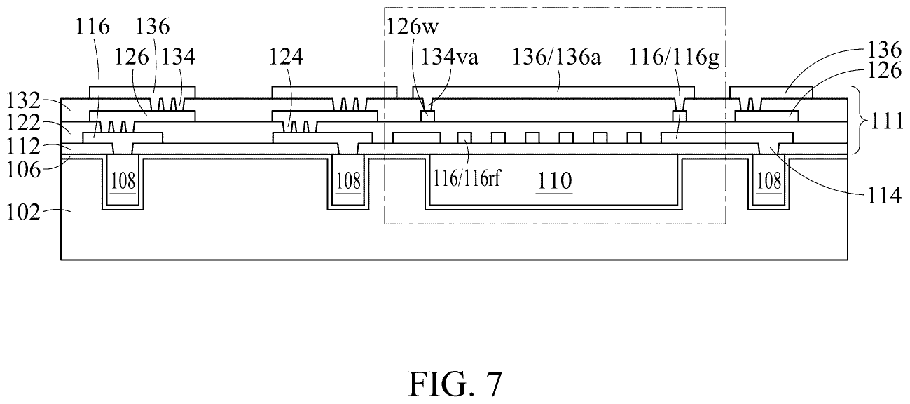

In FIG. 3, a first metallization pattern 116 for a redistribution structure 111 (see FIG. 7) may be formed over a dielectric layer 112 of the redistribution structure 111. The dielectric layer 112 may be formed on the liner layer 106 and over the metal fills 108 and 110. The first metallization pattern 116 may penetrate through the dielectric layer 112 using through vias 114 to contact and couple the metal fills 108 to the first metallization pattern 116. The bottom surface of the dielectric layer 112 may be in contact with the top surface of the liner layer 106. In some embodiments, the dielectric layer 112 is formed of a polymer, such as polybenzoxazole (PBO), polyimide, benzocyclobutene (BCB), or the like. In other embodiments, the dielectric layer 112 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 112 may be formed by any acceptable deposition process, such as spin coating, CVD, plasma enhanced CVD (PECVD), laminating, the like, or a combination thereof. After depositing the dielectric layer 112, openings may be made through the dielectric layer 112 using an acceptable photoetching process, such as described above, the openings corresponding to the through vias 114.

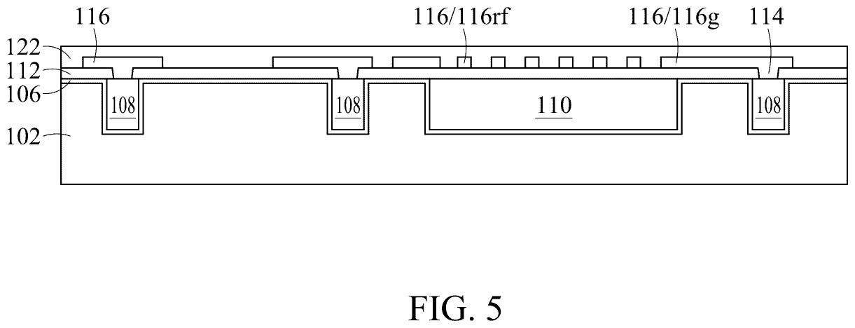

The first metallization pattern 116 may be formed on the dielectric layer 112 and the through vias 114 formed through the openings in the dielectric layer 112 in the same process or in different processes. The first metallization pattern 116 and through vias 114 may be formed using processes and materials similar to those used to form the metal fills 108 and 110. For example, to form first metallization pattern 116 and through vias 114 at the same process, a seed layer may be formed over the dielectric layer 112 and in the openings through the dielectric layer 112 to contact exposed upper surfaces of the metal fills 108. The seed layer may be a single or composite metal layer. A photoresist may then be formed and patterned on the seed layer to form openings therein corresponding to the first metallization pattern 116, which includes the through vias 114. A conductive material is formed in the openings of the photoresist and on the exposed portions of the seed layer. Then, the photoresist and portions of the seed layer on which the conductive material is not formed are removed. The remaining portions of the seed layer and conductive material form the first metallization pattern 116 and through vias 114. Other processes may be used. For example, in some embodiments, the through vias 114 may be formed first, followed by the first metallization pattern 116. In other embodiments, the first metallization pattern 116 may be formed within the dielectric layer 112 such that the upper surface of the dielectric layer 112 (e.g., see dielectric layer 122 in FIG. 5) may be leveled with the upper surface of the first metallization pattern 116.

The first metallization pattern 116 may include a metal grate 116rf which defines an outer portion of an oscillation region. The first metallization pattern 116 may also include a ground metal 116g which couples to the metal grate 116rf.

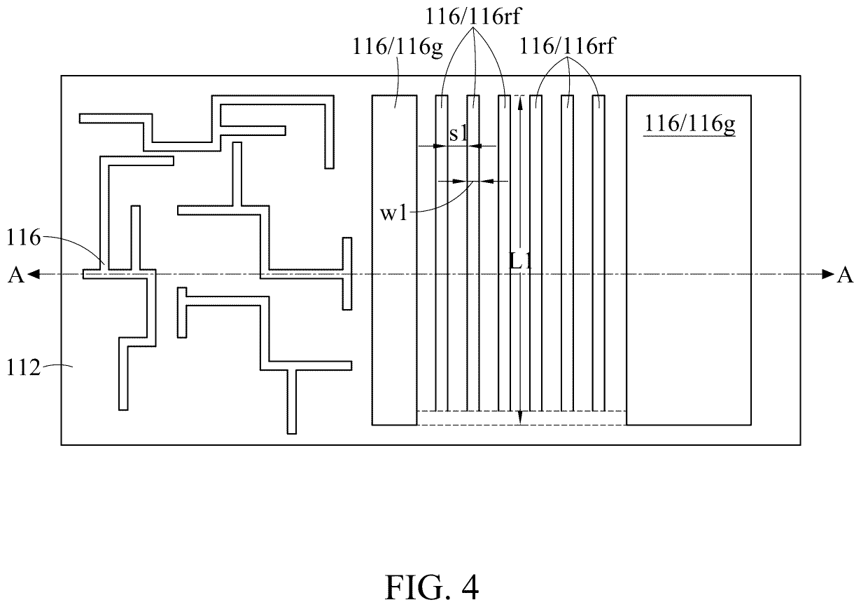

FIG. 4 illustrates a top down view of the structure of FIG. 3, in accordance with some embodiments. The reference line A-A corresponds to the cross-sectional view of FIG. 3. The dielectric layer 112 is shown as well as an example first metallization pattern 116. The metal grate 116rf is illustrated as having multiple parallel metal lines that are spaced apart from each other. These metal lines are used to amplify an antenna signal, which will be explained in greater detail below. The spacing s1 of the metal lines of the metal grate 116rf may be between about 0.1 μm and about 100 μm. The width w1 of the metal lines of the metal grate 116rf may be between about 0.1 μm and about 100 μm. The length L1 of the metal lines of the metal grate 116rf may be between about 10 μm and about 10,000 μm. On one or both ends, as shown in dashed outline, the ends of the metal grate 116rf may all be coupled to each other and to the ground metal 116g.

In FIG. 5, the dielectric layer 122 may be formed on the first metallization pattern 116 and the dielectric layer 112. In some embodiments, the dielectric layer 122 is formed of a polymer, which may be a photo-sensitive material such as PBO, polyimide, BCB, or the like, that may be patterned using a lithography mask. In other embodiments, the dielectric layer 122 is formed of a nitride such as silicon nitride; an oxide such as silicon oxide, PSG, BSG, BPSG; or the like. The dielectric layer 122 may be formed by spin coating, lamination, CVD, the like, or a combination thereof.

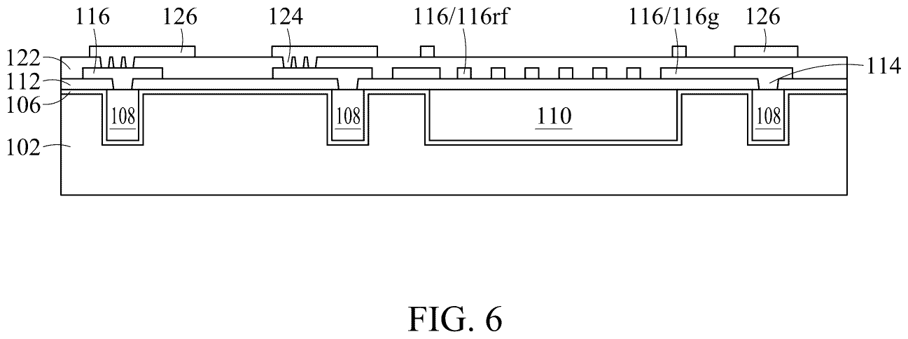

In FIG. 6, the dielectric layer 122 is then patterned to form openings exposing portions of the first metallization pattern 116. The patterning may be formed by an acceptable process, such as by exposing the dielectric layer 122 to light when the dielectric layer 122 is a photo-sensitive material or by etching using, for example, an anisotropic etch. If the dielectric layer 122 is a photo-sensitive material, the dielectric layer 122 can be developed after the exposure. Through vias 124 are formed in the openings through the dielectric layer 122 and a second metallization pattern 126 is formed over the dielectric layer 122. The through vias 124 and second metallization pattern 126 may be formed using processes and materials similar to those described above with respect to the through vias 114 and the first metallization pattern 116.

In FIG. 7, the dielectric layer 132 may be formed on the second metallization pattern 126 and the dielectric layer 122. In some embodiments, the dielectric layer 132 may be formed using processes and materials similar to those discussed above with respect to the dielectric layer 112 and/or dielectric layer 122. The dielectric layer 132 is then patterned to form openings exposing portions of the second metallization pattern 126. The patterning may be formed by an acceptable process, such as described above with respect to the dielectric layer 122. Through vias 134 are formed in the openings through the dielectric layer 132 and a third metallization pattern 136 is formed over the dielectric layer 132. The through vias 134 and third metallization pattern 136 may be formed using processes and materials similar to those described above with respect to the through vias 114 and the first metallization pattern 116. The third metallization pattern 136 includes a patch antenna 136a formed as part of the third metallization pattern 136.

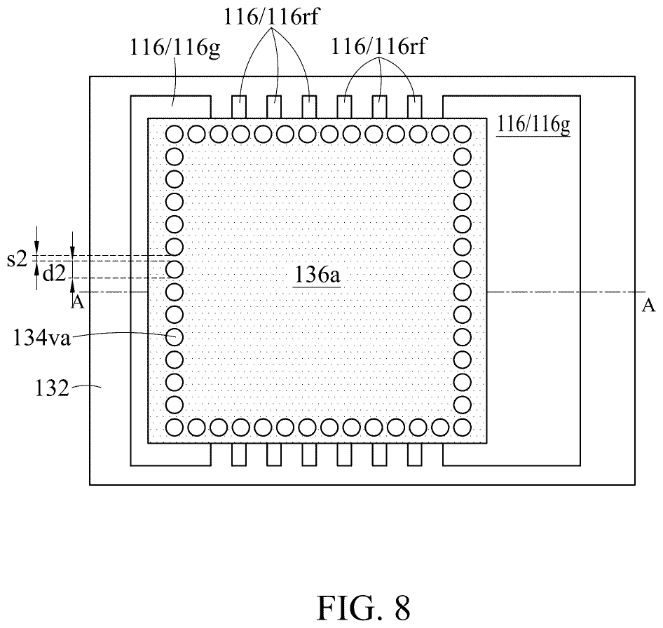

FIGS. 8 through 14 provide a modified top down view of a portion of the structure of FIG. 7 utilizing various options for a through via array 134va of the through vias 134 and a metal wall 126w of the second metallization pattern 126. The top down view of FIGS. 8 through 14 includes a top down view of the dashed box portion of the structure of FIG. 7. The ground metal 116g and metal grate 116rf would be covered by the dielectric layer 132, but are included in these views to show the relationships of each of the illustrated parts. In FIGS. 8 through 10A and 10B, the through via array 134va is shown in dashed outline as, it is actually below the antenna 136a. The antenna 136a is coupled by the through via array 134va to the metal wall 126w of the second metallization pattern 126.

As illustrated in FIG. 8, the through via array 134va may include multiple through vias arranged around a periphery of the footprint of the antenna 136a. Each of the through vias 134 is arranged in a single deep row of through vias 134. They are positioned close together so that the spacing s2 between each of the through vias of the through via array 134va is less than the diameter d2 or width of each of the through-vias. In some embodiments the spacing s2 is 20% to 50% of the width w1.

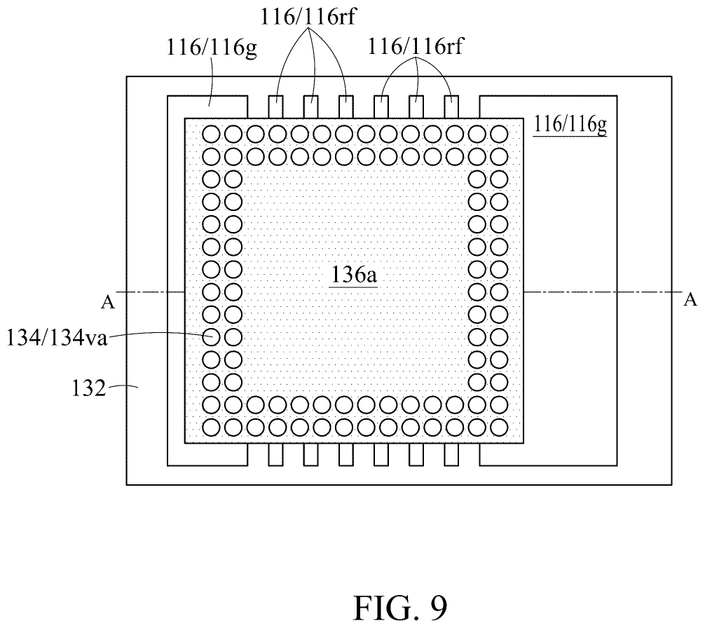

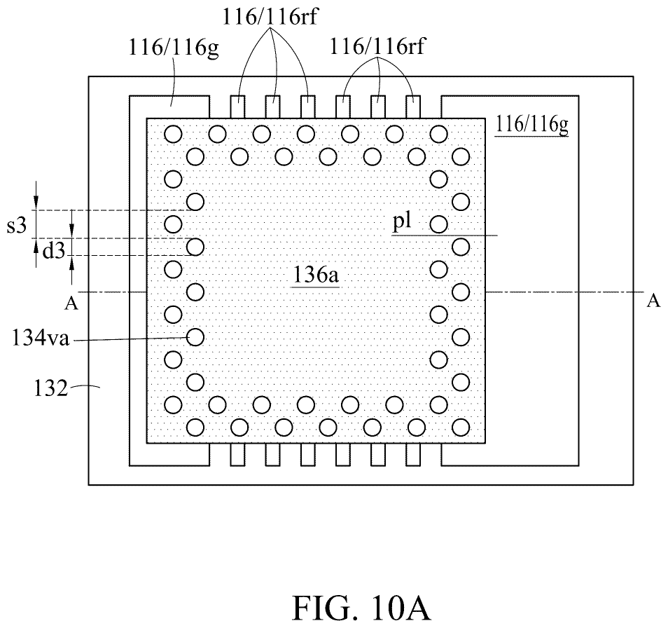

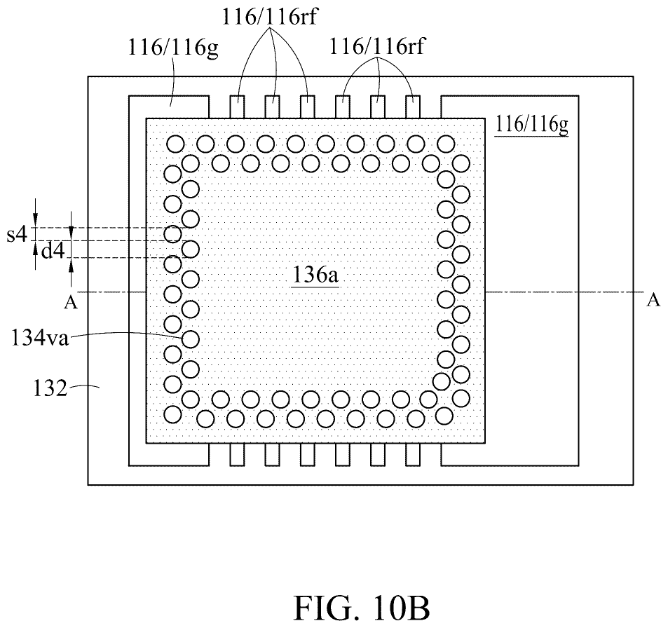

In FIG. 9, the through via array 134va may include a double deep row of through vias 134 aligned to the periphery of the antenna 136a. In some embodiments, the through via array 134va may include one or more additional rows of the through vias 134 on one or more of the sides of the antenna 136a. In some embodiments, the through vias 134 of the through via array 134va may each be horizontally and vertically aligned, such as illustrated in FIG. 9. In other embodiments, however, the through via array 134va may include multiple rows of staggered through vias 134, such as illustrated in FIGS. 10A and 10B.

In FIG. 10A, the staggered through vias 134 are separated in each row by a spacing s3 where s3 is greater than the diameter d3 of each of the through vias 134. As such, a line pl perpendicular to the orientation of the through via array 134va (i.e., perpendicular to the edge direction of the antenna 136a) may fit between the staggered through vias 134 without contacting any of the through vias 134. In FIG. 10B, in accordance with some embodiments, the staggered through vias 134 are separated in each row by a spacing s4, where s4 is less than the diameter d4 of each of the through vias 134. As such, any line pl perpendicular to the orientation of the through via array 134va would contact at least one of the through vias 134. The arrangement of the through via array 134va in FIG. 10B may be beneficial in helping the oscillation region operate more efficiently by causing more of the generated or received radio frequency signals to oscillate in the oscillation region.

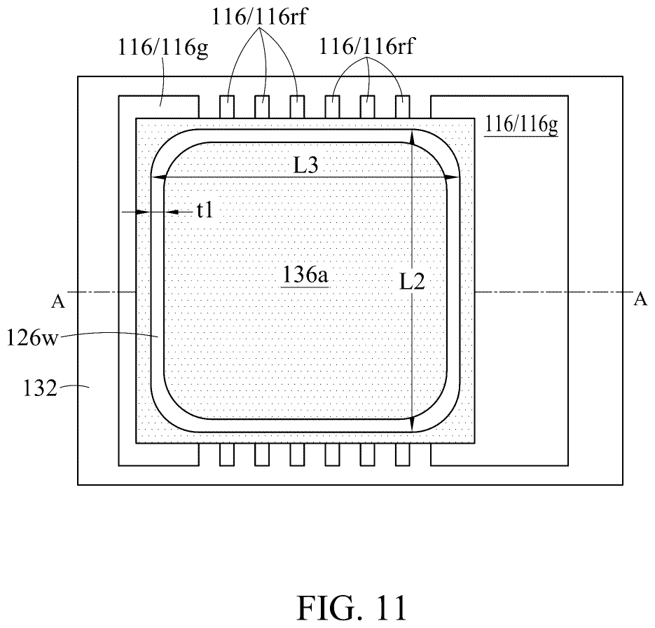

In FIGS. 11 through 14 a metal wall 126w is shown in dashed outline as, it is actually below the antenna 136a. The antenna 136a is coupled by the through via array 134va to the metal wall 126w of the second metallization pattern 126. In FIG. 11, the metal wall 126w is illustrated as being a single solid ring of metal aligned to the periphery of the antenna 136a. The metal wall 126w may be electrically coupled to the antenna 136a by the through via array 134va, while in other embodiments, the metal wall 126w may be electrically floating, i.e., not electrically coupled to the antenna 136a or another metal structure. The metal wall 126w and/or through via array 134va serves as an outer lateral boundary of the oscillation region. The length L2 of the metal wall 126w in a first horizontal dimension and the length L3 of the metal wall 126w in a second horizontal dimension may each be between about 10 μm and about 100,000 μm. The lateral thickness t1 of the metal wall 126w may be between about 0.1 μm and about 20 μm.

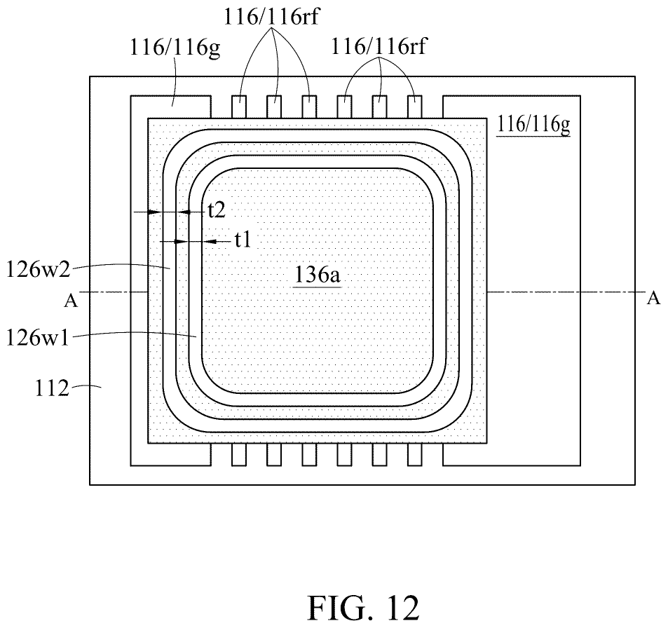

In FIG. 12, the metal wall structure includes a first metal wall 126w1 and a second metal wall 126w2 surrounding the first metal wall 126w1. In some embodiments, the first metal wall 126w1 may be separated from the second metal wall 126w2 by a distance between about 0.1 μm and about 100 μm. In some embodiments, the first metal wall 126w1 and second metal wall 126w2 may be combined with an embodiment including double deep through via array 134va, such as illustrated in FIGS. 9, 10A, and 10B, with one row of the through via array 134va coupled to the first metal wall 126w1 and another row of the through via array 134va coupled to the second metal wall 126w2. In other embodiments, one or more of the first metal wall 126w1 and/or second metal wall 126w2 may be electrically floating, i.e., not electrically coupled to the antenna 136a or another metal structure. In some embodiments, additional metal walls 126wx may be provided in like manner as the first metal walls 126w1 and second metal walls 126w2. The lateral thickness t1 of the first metal wall 126w1 may be between about 0.1 μm and about 20 μm, and the lateral thickness t2 of the second metal wall 126w2 may be between about 0.1 μm and about 20 μm. The lateral thickness t1 may be the same or different than the lateral thickness t2.

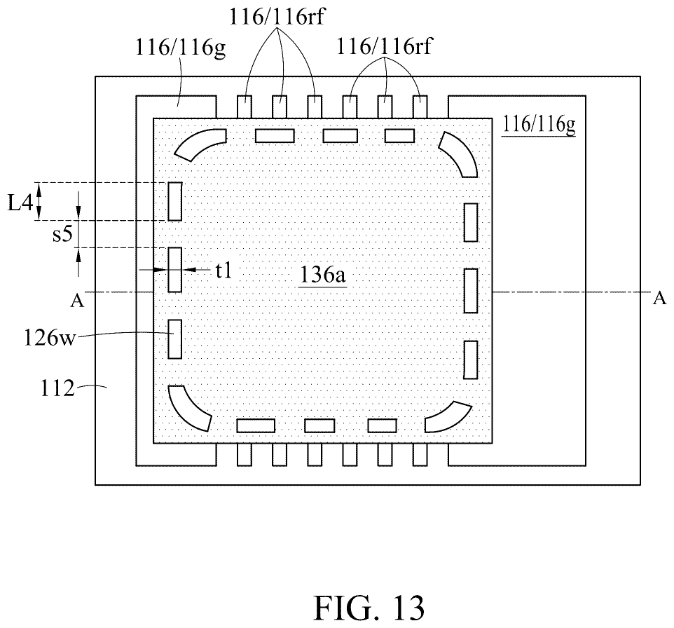

In FIG. 13, the metal wall 126w is segmented. Instead of extending continuously around the antenna 136a footprint, the metal wall 126w has breaks disposed along its length. In some embodiments, the spacing s5 between one end of one segment and the nearest end of an adjacent segment may be between about 0.1 μm and about 20 μm. In some embodiments, the length L4 of each of the segments may be between about 1 μm and about 1000 μm. The lengths and spacing may be standard to all the segments of the metal wall 126w or may vary from segment to segment and space to space. The lateral thickness t1 of the metal wall 126w may be between about 0.1 μm and about 20 μm.

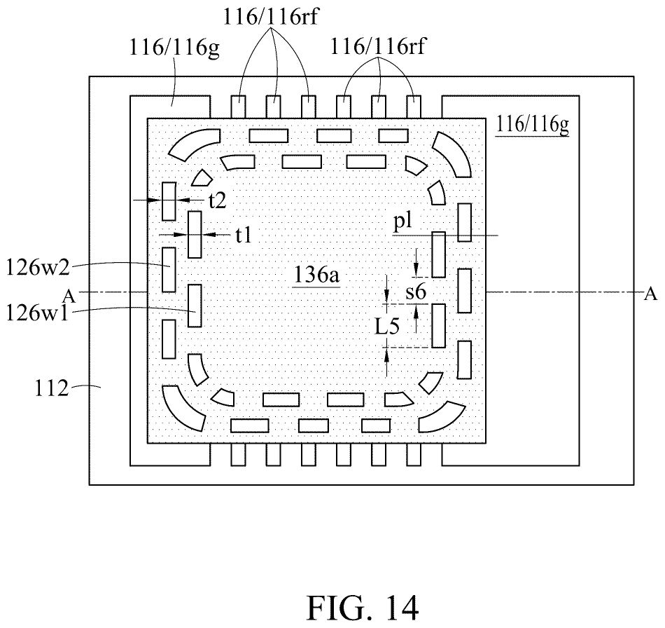

In FIG. 14, the metal wall structure includes a first metal wall 126w1 and a second metal wall 126w2 surrounding the first metal wall 126w1. Each of the first metal wall 126w1 and second metal wall 126w2 may be segmented like the metal wall 126w of FIG. 13. In some embodiments, the segments may be aligned. In other embodiments, such as illustrated in FIG. 14, the segments may be staggered such that a line pl perpendicular to the edge of the antenna 136a would intersect the first metal wall 126w1 and/or the second metal wall 126w2. In such embodiments, the spacing s6 between segments may be smaller than the length L5 of the segments. In some embodiments, the spacing s6 between one end of one segment and the nearest end of an adjacent segment may be between about 0.1 μm and about 20 μm. In some embodiments, the length L5 of each of the segments may be between about 1 μm and about 1000 μm. The lengths and spacing may be standard to all the segments of the metal wall 126w or may vary from segment to segment and space to space. The lateral thickness t1 of the first metal wall 126w1 may be between about 0.1 μm and about 20 μm, and the lateral thickness t2 of the second metal wall 126w2 may be between about 0.1 μm and about 20 μm. The lateral thickness t1 may be the same or different than the lateral thickness t2.

The metal walls 126w or metal wall structures including first metal walls 126w1 and second metal walls 126w2 and so forth of FIGS. 11 through 14 and the through via array 134va of FIGS. 8 through 10A and 10B together provide an oscillation region. A line perpendicular to the edge of the antenna 136a may intersect the metal walls 126w, 126w1, and/or 126w2 (depending on the design used). If such a line, for example, were representative of a radio signal transmitting from or receiving to the antenna 136a, the signal would reflect off of the first metal wall 126w1 and/or second metal wall 126w2 and oscillate between sides of the metal walls. In oscillating, the signals received or transmitted can be additive, causing a signal boost before being received by the antenna 126a (as in the case of a received signal) or leaving the oscillation region, propagating away from the antenna 126a (as in the case of transmitting a signal). The oscillation may also be similarly aided by the many individual and potentially overlapping through vias 134 of the through via array 134va.

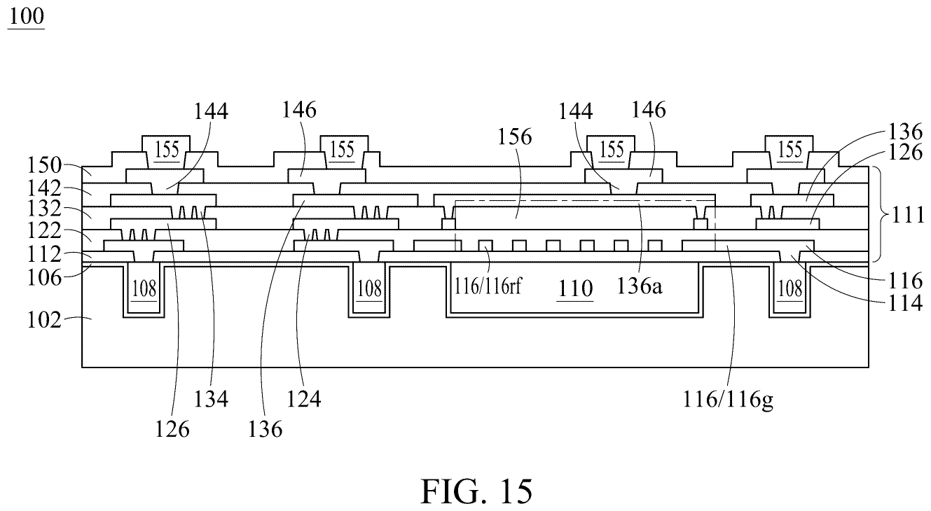

In FIG. 15, after the third metallization pattern 136 is formed, a dielectric layer 142 is formed over the third metallization pattern 136. The dielectric layer 142 may be formed using processes and materials similar to those used to form the dielectric layer 112. The dielectric layer 142 is then patterned to form openings exposing portions of the third metallization pattern 136, including the antenna 136a. The patterning may be formed by an acceptable process, such as described above with respect to the dielectric layer 122. Through vias 144 are formed in the openings through the dielectric layer 142 and a fourth metallization pattern 146 is formed over the dielectric layer 142. In some embodiments, the through vias 144 and fourth metallization pattern 146 may be formed using processes and materials similar to those described above with respect to the through vias 114 and the first metallization pattern 116. In other embodiments, the through vias 144 and fourth metallization pattern 146 may be formed using materials alternate to those used to form the through vias 114 and first metallization pattern 116. For example, the through vias 144 and fourth metallization pattern 146 may be formed of aluminum using a seed layer, photoresist, and plating process such as described above. Utilizing aluminum for example, may provide desired physical and electrical properties between the subsequently formed connectors 155 and the material of the redistribution structure 111. For example, the fourth metallization pattern 146 may be thicker than the metallization patterns of the redistribution structure 111 and produce less diffusion of conductive materials into the surrounding dielectric layers and passivation layer 150.

Following the formation of the through vias 144 and fourth metallization pattern 146, the passivation layer 150 may be formed over the fourth metallization pattern 146 to protect the fourth metallization pattern from further processing. The passivation layer 150 may be formed of any suitable material, such as silicon nitride, silicon oxynitride, silicon oxycarbonitride, silicon carbide, polyimide, the like, or combinations thereof. After the passivation layer 150 is formed, openings corresponding to the connectors 155 may be made through the passivation layer 150 to expose portions of the fourth metallization pattern 146 through the passivation layer 150.

Connectors 155 are formed for connection to an integrated circuit device subsequently attached to the redistribution structure 111 by the fourth metallization pattern 146. The connectors 155 may be microbumps, having bump portions on and extending along the major surface of the passivation layer 150 and via portions extending through the passivation layer 150 to physically and electrically couple the fourth metallization pattern 146. As a result, the connectors 155 are electrically coupled to features of the redistribution structure 111 and one or more of the connectors 155 are coupled through the redistribution structure 111 to the metal fill 108. The connectors 155 may be formed of the same material as the fourth metallization pattern 146 or third metallization pattern 136.

In some embodiments, the connectors 155 may include an underbump metallization (UBM) and conductive connector on the UBM. The conductive connector of the connectors 155 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The connectors 155 may include a conductive material such as solder, copper, aluminum, gold, nickel, silver, palladium, tin, the like, or a combination thereof. In some embodiments, the connectors 155 are formed by forming a layer of solder over the UBMs through evaporation, electroplating, printing, solder transfer, ball placement, or the like. Once a layer of solder has been formed on the UBMs, a reflow may be performed in order to shape the material into the desired bump shapes. In another embodiment, the connectors 155 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Following the formation of the connectors 155, the first package component 100 is formed. The first package component 100 includes an oscillation region 156, such as outlined by the dashed box illustrated in FIG. 15. The oscillation region 156 causes RF signals entering the metal grate 116rf or leaving the antenna 136a to bounce within the oscillation region 156, for example off of the through via array 134va, off of the metal grate 116rf, off the antenna 136a, and off the metal wall 126w, the RF signals adding and boosting their signals.

As noted above, the first package component 100 may be formed in a wafer and may be one of multiple first package components 100 formed in the wafer, each one of the first package components corresponding to first package region, a second package region, etc. Following the formation of the first package components 100, in some embodiments the first package components 100 may be singulated from one another in a singulation process. In other embodiments, integrated circuit dies may be mounted to the first package components 100 prior to singulation. The singulation process may be performed by sawing along scribe line regions, e.g., between the first package region (as illustrated in FIG. 15) and an adjacent second package region. The sawing singulates the first package component 100 from the adjacent first package component 100. The resulting, singulated first package component contains the corresponding package region and may then be used to attach appropriate dies and used in further processing. In some embodiments, the singulation process is performed after the integrated circuit dies 50 are attached to the first package component 100.

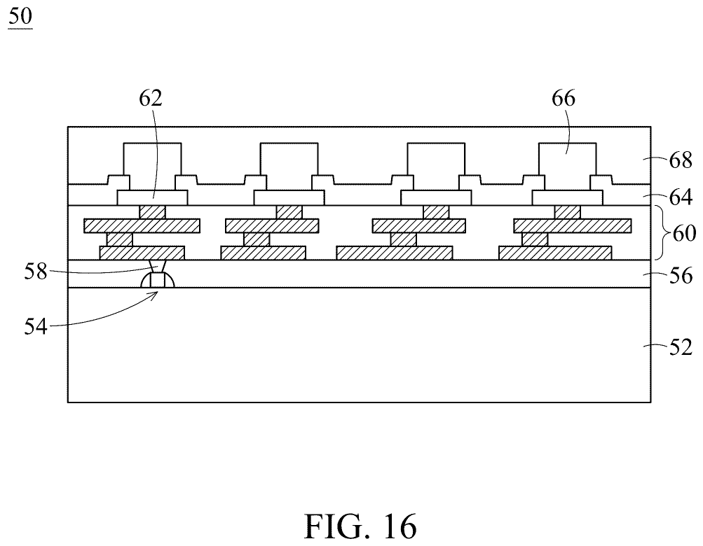

FIG. 16 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) transmit/receiving die, an RF Baseband (BB) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 16), sometimes called a front side, and an inactive surface (e.g., the surface facing downwards in FIG. 16), sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and source/drain regions of the transistors. Source/drain region(s) may refer to a source or a drain, individually or collectively dependent upon the context. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure 60.

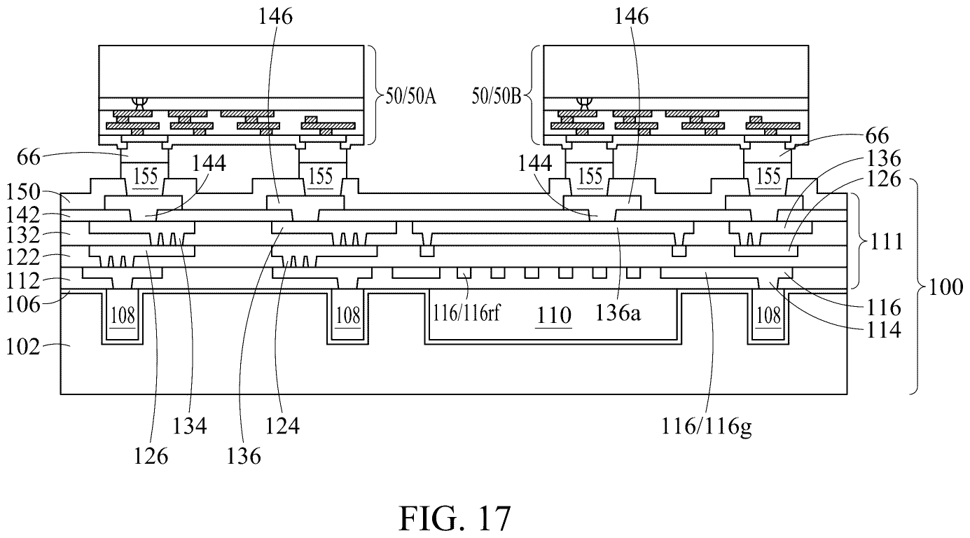

In FIG. 17, integrated circuit dies 50 (e.g., a first integrated circuit die 50A and a second integrated circuit die 50B) are connected to the connectors 155. A desired type and quantity of integrated circuit dies 50 are adhered in each of the package regions corresponding to each of the first package components 100. In the embodiment shown, multiple integrated circuit dies 50 are connected adjacent one another, including the first integrated circuit die 50A and the second integrated circuit die 50B in each of the package regions. The first integrated circuit die 50A may be a logic device, such as a central processing unit (CPU), a graphics processing unit (GPU), a system-on-a-chip (SoC), a microcontroller, or the like. In one embodiment, the first integrated circuit die 50A is a SoC with Baseband (BB) RF functions for RF signal processing, such as 5G/6G RF signals. The second integrated circuit die 50B may be a memory device, such as a dynamic random access memory (DRAM) die, a static random access memory (SRAM) die, a hybrid memory cube (HMC) module, a high bandwidth memory (HBM) module, or the like. In one embodiment, the second integrated circuit die 50B may be a transmitting/receiving (tx/rx) die which is coupled to the antenna 136a. Additional integrated circuit dies 50 with any of the aforementioned functionality may also attached as desired. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The first and second integrated circuit dies 50A and 50B may have different sizes (e.g., different heights and/or surface areas), or may have the same size (e.g., same heights and/or surface areas).

The integrated circuit dies 50 may be attached using any suitable process, such as a pick and place process to align the die connectors 66 with the connectors 155 and couple the die connectors 66 to the connectors 155 using a die attachment process, such as reflowing a solder material to adhere the die connectors 66 to the connectors 155. Other die attachment processes may be used, such as utilizing a direct metal to metal bond between the connectors 66 and the connectors 155. In some embodiments, the connectors 155 have an epoxy flux formed thereon before they are reflowed with at least some of the epoxy portion of the epoxy flux remaining after the first and second integrated circuit dies 50A and 50B are attached to the first package component 100.

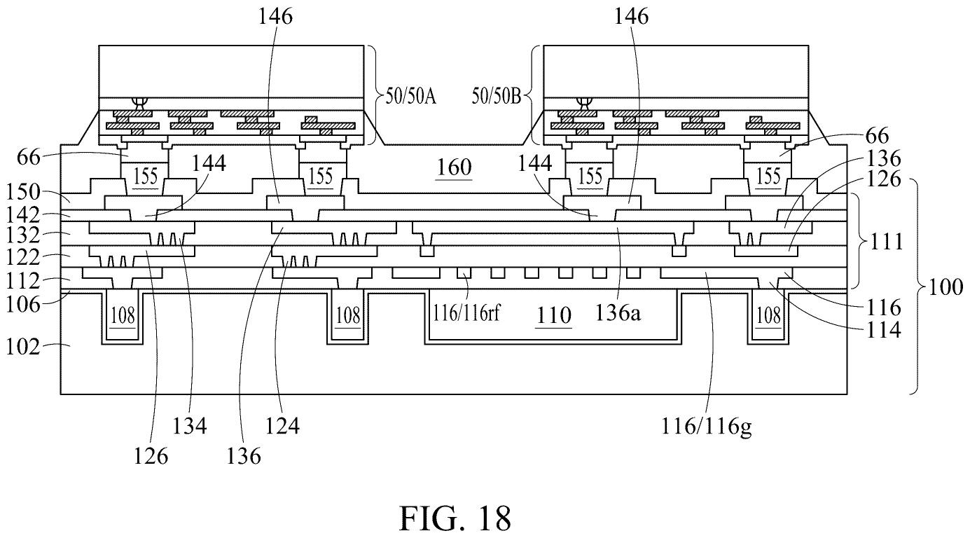

In FIG. 18, an underfill 160 is formed between the first package component 100 and the first integrated circuit die 50A and the second integrated circuit die 50B, surrounding the connectors 155 and connectors 66. The underfill 160 may reduce stress and protect the joints resulting from the reflowing of the connectors 155. The underfill 160 may be formed by a capillary flow process after the first and second integrated circuit dies 50A and 50B are attached. In embodiments where the epoxy flux is formed, it may act as the underfill. As seen in FIG. 18, in some embodiments, the underfill 160 may extend at least partially up a sidewall of the first and second integrated circuit dies 50A and 50B. In some embodiments, the underfill 160 may continue to extend all the way to the uppermost surface (i.e., the backsides of the first and second integrated circuit dies 50A and 50B). In such embodiments, the upper surface of the underfill 160 may dip down between the first and second integrated circuit dies 50A and 50B in a manner similar to that illustrated in FIG. 18.

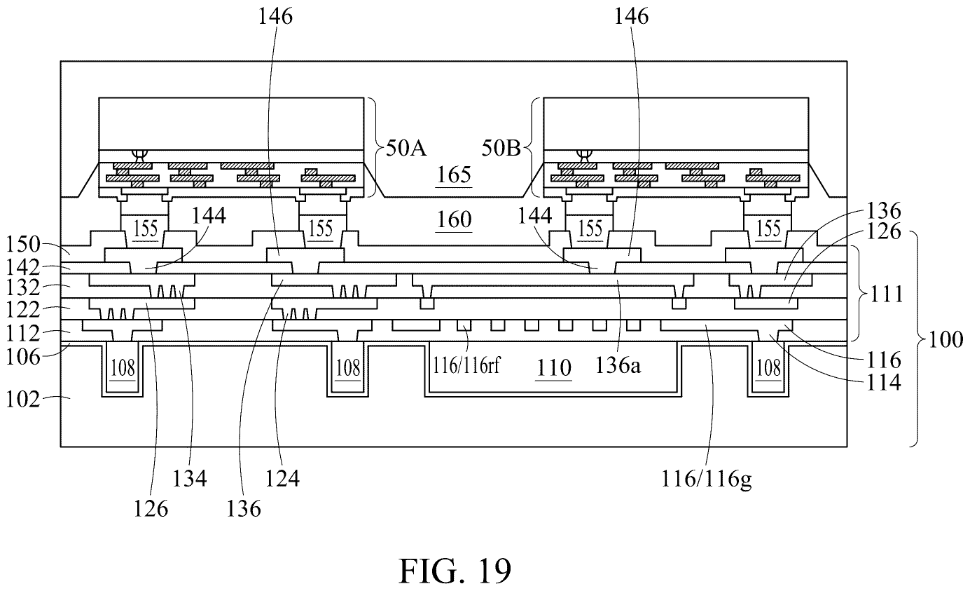

In FIG. 19, an encapsulant 165 is formed on and around the various components, including on and around the underfill 160 and on and around the first and second integrated circuit dies 50A and 50B. After formation, the encapsulant 165 encapsulates the first and second integrated circuit dies 50A and 50B. The encapsulant 165 may be a molding compound, epoxy, or the like. The encapsulant 165 may be applied by compression molding, transfer molding, or the like, and may be formed over the underfill 160 such that the first and second integrated circuit dies 50A and 50B are buried or covered. The encapsulant 165 is further formed in gap regions between the first and second integrated circuit dies 50A and 50B. The encapsulant 165 may be applied in liquid or semi-liquid form and then subsequently cured.

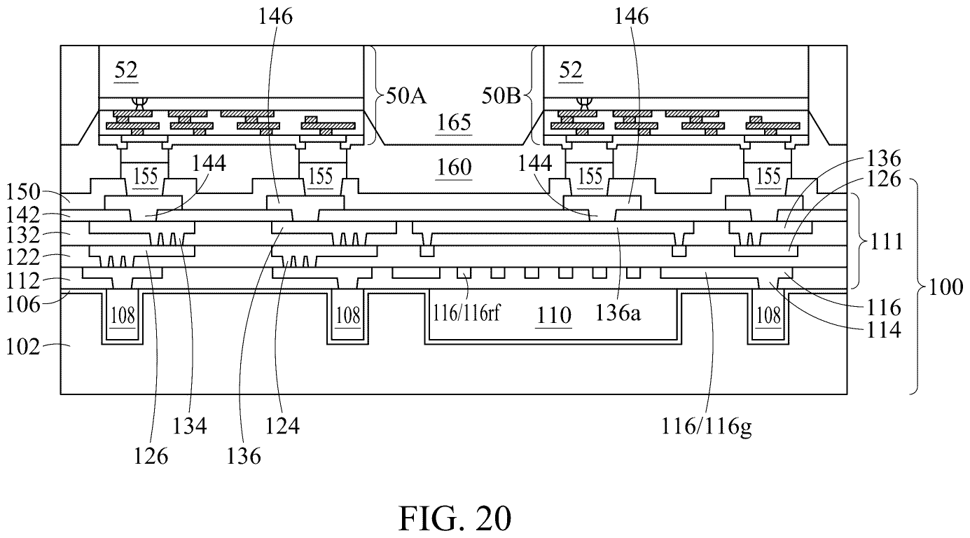

In FIG. 20, a planarization process is performed on the encapsulant 165 to expose the back side of the first and second integrated circuit dies 50A and 50B. In some embodiments, the planarization process may continue to operate to thin the substrate 52 of the first and second integrated circuit dies 50A and 50B. Top surfaces of the first and second integrated circuit dies 50A and 50B and encapsulant 165 are substantially coplanar after the planarization process within process variations. The planarization process may be, for example, a chemical-mechanical polish (CMP), a grinding process, or the like.

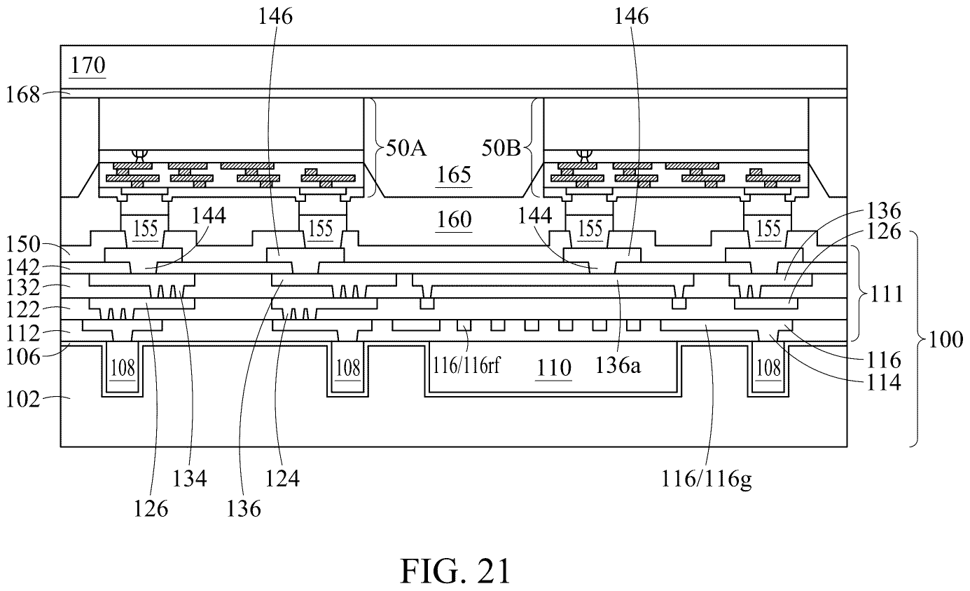

In FIG. 21, a carrier substrate 170 is mounted to the upper side of the structure of FIG. 20 by a release layer 168. The carrier substrate 170 may be a glass carrier substrate, a ceramic carrier substrate, or the like. The release layer 168 may be formed of a polymer-based material, which may be removed along with the carrier substrate 170 in subsequent steps. In some embodiments, the release layer 168 is an epoxy-based thermal-release material, which loses its adhesive property when heated, such as a light-to-heat-conversion (LTHC) release coating. In other embodiments, the release layer 168 may be an ultra-violet (UV) glue, which loses its adhesive property when exposed to UV lights. The release layer 168 may be dispensed as a liquid and cured, may be a laminate film laminated onto the carrier substrate 170 or the encapsulant 165 and first and second integrated circuit dies 50A and 50B, or may be the like. The top surface of the release layer 168 may be leveled and may have a high degree of planarity.

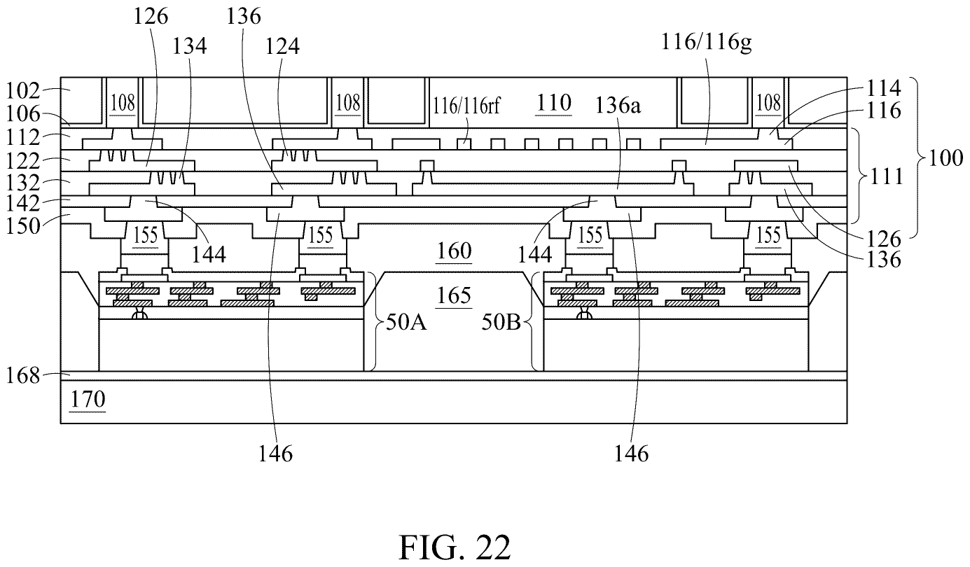

In FIG. 22, the structure of FIG. 21 is flipped over and the substrate 102 is thinned to expose the metal fills 108 and 110. The thinning process may be a grinding process, a CMP process, an etching process, or combinations thereof. Following the thinning process, a portion of the liner layer 106 is removed which was previously along a bottom of the metal fills 108 and 110, along with a portion of the substrate 102. In some embodiments, some of the metal fill 108 and/or metal fill 110 may be removed, for example, if the metal fill 108 or metal fill 110 was thicker than the other.

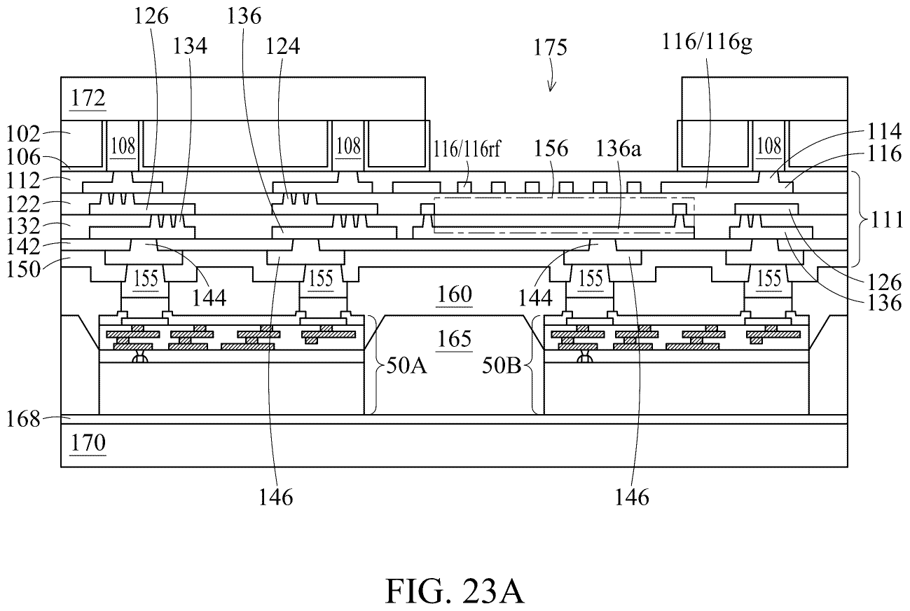

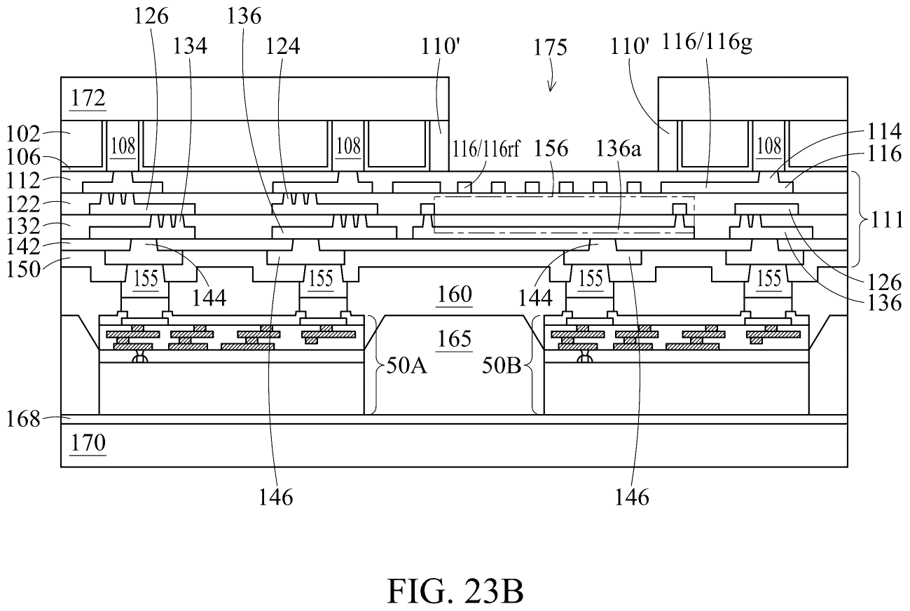

In FIG. 23A, a photomask 172 is formed over the substrate 102 and patterned to form an opening corresponding to the metal fill 110. Then the metal fill 110 is etched to form a cavity 175 in the substrate 102 corresponding to the antenna 136a. Because RF signals do not easily propagate through metal or semiconductor materials, the cavity 175 is made in the semiconductor substrate 102 to allow the RF signals in and out of the oscillation region 156.

In FIG. 23B, the photomask 172 is formed over the substrate 102 and patterned to form an opening over the metal fill 110. In FIG. 23B, however, the photomask 172 is smaller than the metal fill 110 but as large as the metal grate 116rf. Thus, when the metal fill 110 is etched to form the cavity 175 in the substrate 102, the cavity 175 may have a portion 110′ of the metal fill 110 remaining on side walls of the cavity 175.

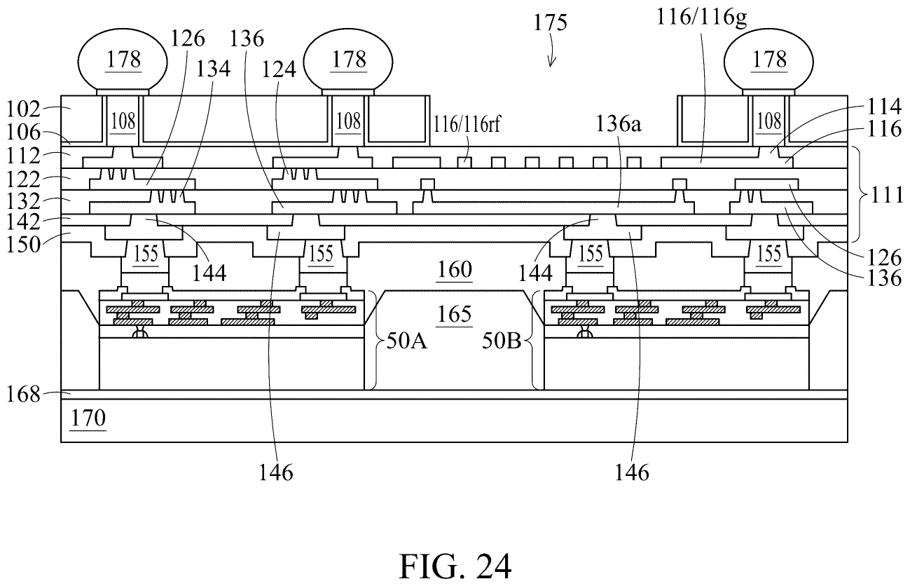

In FIG. 24, the photomask 172 is removed by an acceptable process, such as by an ashing process. Then, conductive connectors 178 are formed over the metal fills 108 which serve as through vias for the substrate 102. In some embodiments bond pads 176 may be formed first over the metal fills 108. The bond pads 176 are electrically coupled to the metal fill 108, the redistribution structure 111, and the first and/or second integrated circuit dies 50A and 50B.

The bond pads 176 may be formed using similar processes and materials used to form the first metallization pattern 116. In some embodiments, the bond pads 176 are formed by forming recesses (not shown) into a dielectric layer (not shown) disposed on the substrate 102. The recesses may be formed to allow the bond pads 176 to be embedded into the dielectric layer. In other embodiments, the recesses are omitted as the bond pads 176 may be formed on the dielectric layer or on the substrate 102. In some embodiments, the bond pads 176 include a thin seed layer (not shown) made of copper, titanium, nickel, gold, palladium, the like, or a combination thereof. The conductive material of the bond pads 176 may be deposited over the thin seed layer. The conductive material may be formed by an electro-chemical plating process, an electroless plating process, CVD, atomic layer deposition (ALD), PVD, the like, or a combination thereof. In an embodiment, the conductive material of the bond pads 176 is copper, tungsten, aluminum, silver, gold, the like, or a combination thereof.

In some embodiments, the bond pads 176 are UBMs that include three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the bond pads 176. Any suitable materials or layers of material that may be used for the bond pads 176 are fully intended to be included within the scope of the current application.

Conductive connectors 178 are formed on the bond pads 176. The conductive connectors 178 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 178 may include a conductive material such as solder, copper, aluminum, gold, nickel, silver, palladium, tin, the like, or a combination thereof. In some embodiments, the conductive connectors 178 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 178 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

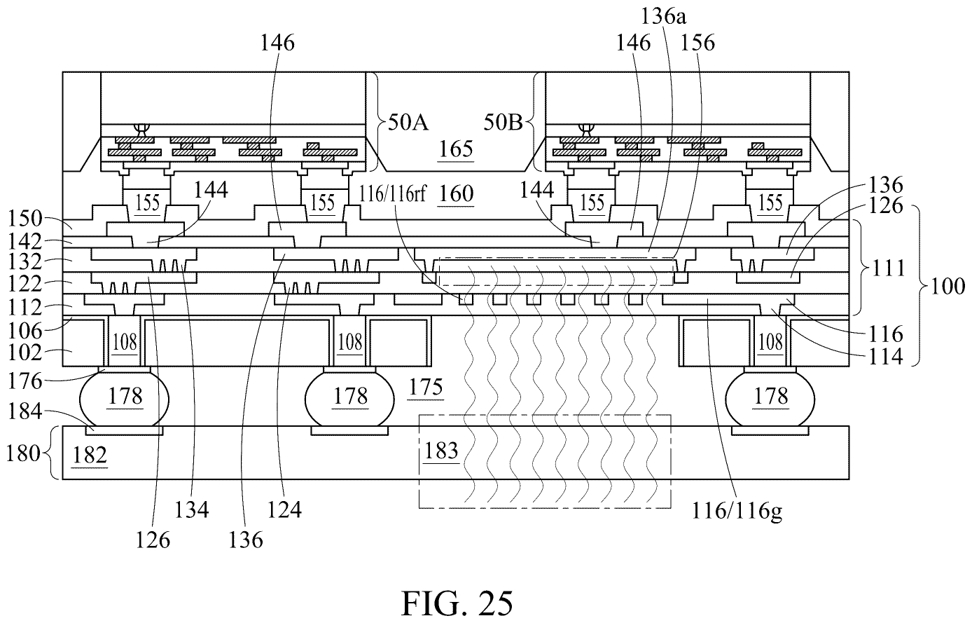

In FIG. 25, a carrier substrate de-bonding is performed to detach (or “de-bond”) the carrier substrate 170 from the top of the structure, e.g., the encapsulant 165 and first and second integrated circuit dies 50A and 50B. In accordance with some embodiments, the de-bonding includes projecting a light such as a laser light or an UV light on the release layer 168 so that the release layer 168 decomposes under the heat of the light and the carrier substrate 170 can be removed.

In embodiments where the first package component 100 was not previously singulated, the first package component 100, including the first and second integrated circuit dies 50A and 50B may be singulated from neighboring package components. The singulation process described above may be used to perform the singulation.

The structure is then flipped over and attached by the conductive connectors 178 to a package substrate 180 using the conductive connectors 178. The package substrate 180 includes a substrate core 182 and bond pads 184 over the substrate core 182. The substrate core 182 may be made of a non metal or non semiconductor material, such as an organic material, such as BT resin (bismaleimide triazine resin), a build-up ABF resin, or MIS (molded interconnect substrate) material, or the like. The substrate core 182 is, in one alternative embodiment, based on an insulating core such as a fiberglass reinforced resin core. One example core material is fiberglass resin such as FR4. The substrate core 182 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 182 may also include metallization layers and vias (not shown), with the bond pads 184 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 182 is substantially free of active and passive devices.

The package substrate 180 may have a keep out zone 183 aligned to the substrate cavity 175 and oscillation region 156, to allow the passage of RF signals to and from the antenna 136a without interference from conductive or semi-conductive materials.

In some embodiments, the conductive connectors 178 are reflowed to attach the conductive connectors 178 to the bond pads 184. The conductive connectors 178 electrically and/or physically couple the package substrate 180, including metallization layers in the substrate core 182, to the conductive elements of the first package component 100 and first and second integrated circuit dies 50A and 50B.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

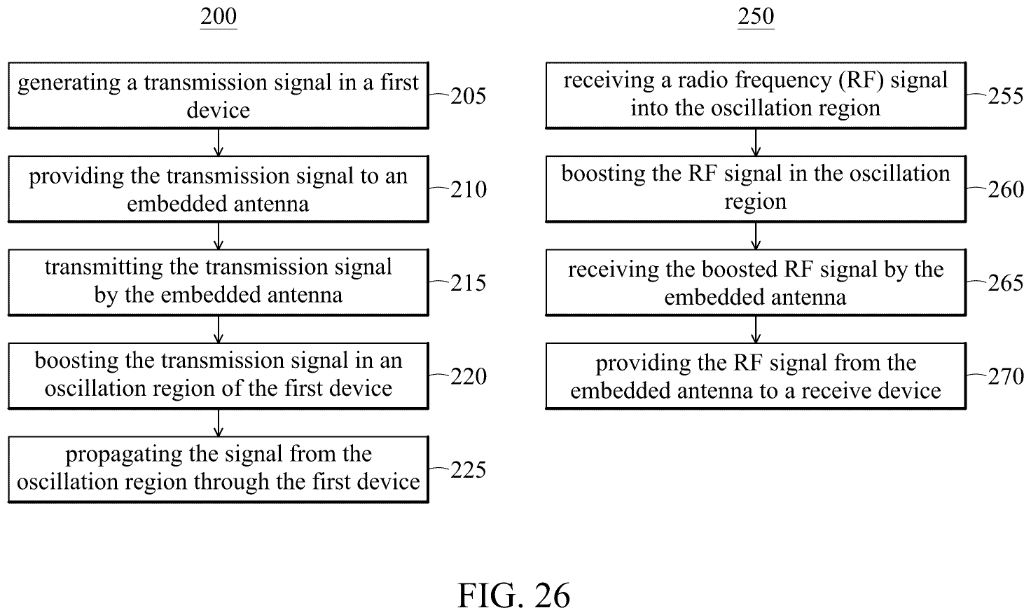

FIG. 26 illustrates a flow diagram for a process 200 and a flow diagram for a process 250. In the process 200 at the first element 205, a transmission signal is generated in a first device, such as the second integrated device die 50B. At 210, the transmission signal is provided to an embedded antenna, such as the antenna 136a. At 215, the transmission signal is transmitted by the embedded antenna. At 220, the transmission signal is boosted in an oscillation region of the first device, such as the oscillation region 156. At 225 the signal is propagated from the oscillation region through the first device, for example beyond the metal grate 116rf. In the process 250 at the first element 255, an RF signal is received into an oscillation region of a first device, such as the oscillation region 256. At 260, the RF signal is boosted in the oscillation region. At 265, the boosted RF signal is received by an embedded antenna, such as the embedded antenna 136a. At 270 the RF signal is provided from the embedded antenna to a receive device, such as the second integrated circuit die 50B.

Embodiments may achieve advantages. Embodiments provide an oscillation region for an embedded antenna. The oscillation region provides a better transmitted signal or received signal for the embedded antenna, which is suitable for 5G and/or 6G signals and their associated RF signal frequency ranges (e.g., for the upcoming 5th Gen. (5.8 GHz) and 5th Gen. high frequency (29˜38 GHz and 77˜120 GHz) RF transceiver). Given the simplified embedding processes, these devices are suitable for use in highly integrated devices, such as portable, wearable, internet of things (IoT), and smart phone products. Embedding the antenna in a metallization layer and providing an oscillation region aligned to the antenna provides the ability to utilize an embedded antenna at the same production cost as without. Yet the embedded antenna cavity shrinks the footprint normally needed to utilize an embedded antenna, which must typically be walled off from the rest of the structure. The thicknesses of the various layers may be tuned for specific application and to meet packaging requirements.

One embodiment is a method including forming a metal grate in a first metal layer of an interconnect. The method also includes forming an oscillation region aligned to the metal grate. The method also includes forming an antenna in a second metal layer of the interconnect, the antenna aligned to the oscillation region and the metal grate. The method also includes coupling a first die to the antenna, the first die may include a transmitting and/or receiving die. The method also includes encapsulating the first die by an encapsulant to form a first package. In an embodiment, the method further includes coupling the first package to a first substrate, the first substrate including an organic material. In an embodiment, the first substrate has a metal free zone aligned to the antenna. In an embodiment, the method further includes originating a signal in the first die, transmitting the signal by the antenna, boosting the signal by the oscillation region, and propagating the signal outwardly from the oscillation region through one or more dielectric layers of the first package. In an embodiment, the method further includes removing a portion of a semiconductor substrate of the first package to form an oscillation cavity aligned to the oscillation region. In an embodiment, the method further includes electrically coupling the metal grate to a ground source metal. In an embodiment, forming the oscillation region includes forming a metal wall in a third metal layer of the interconnect, the third metal layer interposed between the first metal layer and the second metal layer, the metal wall forming a periphery of the oscillation region, and forming a via wall in a via layer of the interconnect, the via layer interposed between the third metal layer and the second metal layer. In an embodiment, the metal wall is segmented.

Another embodiment is a method including generating a transmission signal in a first device. The method also includes providing the transmission signal to an embedded antenna. The method also includes transmitting the transmission signal by the embedded antenna. The method also includes boosting the transmission signal in an oscillation region of the first device. The method also includes propagating the signal from the oscillation region through the first device. In an embodiment, the first device includes a semiconductor substrate having a portion of the semiconductor substrate removed corresponding to the oscillation region. In an embodiment, the method further includes receiving a radio frequency (RF) signal into the oscillation region, boosting the RF signal in the oscillation region, receiving the boosted RF signal by the embedded antenna, and providing the RF signal from the embedded antenna to a receive device. In an embodiment, the method further includes passing the transmission signal from the oscillation region through a grounded metal grate, the grounded metal grate embedded in the first device. In an embodiment, the antenna is embedded in a redistribution layer of the first device.

Another embodiment is a device including a first integrated circuit die, the first integrated circuit die corresponding to a transmit and/or receive die. The device also includes a redistribution structure coupled to the first integrated circuit die, the redistribution structure including a first embedded antenna coupled to the first integrated die. The device also includes an oscillation region aligned to the first embedded antenna, the oscillation region embedded in insulating layers of the redistribution structure. The device also includes a semiconductor substrate attached to the redistribution structure, the semiconductor substrate having an oscillation cavity disposed therein, the oscillation cavity aligned to the oscillation region. In an embodiment, the oscillation region is surrounded by a metal wall, the metal wall coupled to the embedded antenna by a first via array. In an embodiment, the first via array includes two or more rows of vias surrounding the oscillation region. In an embodiment, the oscillation region extends from the antenna to a metal grate disposed opposite the first embedded antenna. In an embodiment, the oscillation region is laterally surrounded by a metal wall structure, the metal wall structure coupled to the antenna by one or more vias. In an embodiment, the metal wall structure includes one or more continuous rings or one or more segmented rings. In an embodiment, the oscillation region is encircled by a via array including one or more rows of vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
generating a transmission signal in a first device;
providing the transmission signal to an embedded antenna;
transmitting the transmission signal by the embedded antenna;
boosting the transmission signal in an oscillation region of the first device; and
propagating the transmission signal from the oscillation region through the first device.

2. The method of claim 1, wherein the first device includes a semiconductor substrate having a portion of the semiconductor substrate removed corresponding to the oscillation region.

3. The method of claim 1, further comprising:
receiving a radio frequency (RF) signal into the oscillation region;
boosting the RF signal in the oscillation region;
receiving the boosted RF signal by the embedded antenna; and
providing the RF signal from the embedded antenna to a receive device.

4. The method of claim 1, further comprising:
passing the transmission signal from the oscillation region through a grounded metal grate, the grounded metal grate embedded in the first device.

5. The method of claim 1, wherein the antenna is embedded in a redistribution layer of the first device.

6. The method of claim 1, wherein the oscillation region is surrounded by a metal wall, the metal wall coupled to the embedded antenna by a first via array.

7. The method of claim 6, wherein the first via array comprises two or more rows of vias surrounding the oscillation region.

8. A device comprising:
a first integrated circuit die, the first integrated circuit die corresponding to a transmit and/or receive die;
a redistribution structure coupled to the first integrated circuit die, the redistribution structure including a first embedded antenna coupled to the first integrated circuit die;
an oscillation region aligned to the first embedded antenna, the oscillation region embedded in insulating layers of the redistribution structure; and
a semiconductor substrate attached to the redistribution structure, the semiconductor substrate having an oscillation cavity disposed therein, the oscillation cavity aligned to the oscillation region.

9. The device of claim 8, wherein the oscillation region extends from the first embedded antenna to a metal grate disposed opposite the first embedded antenna.

10. The device of claim 8, wherein the oscillation region is laterally surrounded by a metal wall structure, the metal wall structure coupled to the first embedded antenna by one or more vias.

11. The device of claim 10, wherein the metal wall structure comprises one or more continuous rings or one or more segmented rings.

12. The device of claim 8, wherein the oscillation region is encircled by a via array comprising one or more rows of vias.

13. The device of claim 8, wherein the oscillation cavity extends through the semiconductor substrate.

14. A device comprising:
a first integrated circuit die, the first integrated circuit die corresponding to a transmit and/or receive die;
an interconnect structure coupled to the first integrated circuit die, wherein the interconnect structure comprises:
a metal grate in a first metal layer of the interconnect structure; and
an antenna in a second metal layer of the interconnect structure, wherein the antenna is aligned with the metal grate, wherein the antenna is electrically coupled to the first integrated circuit die; and
a first substrate attached to the interconnect structure, wherein the interconnect structure is between the first substrate and the first integrated circuit die, the first substrate having an oscillation cavity disposed therein, the oscillation cavity aligned to the metal grate.

15. The device of claim 14, wherein the metal grate is between the antenna and the first substrate.

16. The device of claim 14, wherein the oscillation cavity extends completely through the first substrate.

17. The device of claim 14, further comprising:
metal features extending through the first substrate; and
external connectors on the metal features, wherein the metal features are between the external connectors and the interconnect structure.

18. The device of claim 17, further comprising:
a second substrate attached to the external connectors, wherein the second substrate has a metal keep out zone aligned to the antenna.

19. The device of claim 14, further comprising:
a metal wall in a third metal layer of the interconnect structure, the third metal layer being between the first metal layer and the second metal layer, the metal wall extending along a periphery of the antenna in a plan view; and
a via wall in a via layer of the interconnect structure, the via layer being between the third metal layer and the second metal layer, the via wall electrically coupling the antenna to the metal wall.

20. The device of claim 19, wherein the metal wall comprises a plurality of discrete sections.
